(19) United States
(12) Patent Application Publication
(10) Pub. No.: US 2021/0149784 A1
(43) Pub. Date: May 20, 2021

(54) METHODS, SYSTEMS, AND MEDIA FOR INITIATING AND MONITORING INSTANCES OF WORKFLOWS

(71) Applicant: Sidewalk Labs LLC, New York, NY (US)

(72) Inventors: Kabir Soorya, Long Island City, NY (US); Violet Whitney, Long Island City, NY (US); Douwe Osinga, New York, NY (US); Jack Amadeo, Brooklyn, NY (US); Difei Chen, New York, NY (US); Brian Ho, New York, NY (US); Okalo Ikhena, New York, NY (US); Amanda Meurer, Brooklyn, NY (US); Samara Trilling, New York, NY (US); Dan Vanderkam, Brooklyn, NY (US)

(21) Appl. No.: 16/951,807

(22) Filed: Nov. 18, 2020

Related U.S. Application Data
(60) Provisional application No. 62/936,885, filed on Nov. 18, 2019.

(51) Int. Cl. G06F 11/34; G06F 30/20; G06F 9/451

(52) U.S. Cl. CPC G06F 11/34; G06F 9/451; G06F 30/20

(57) ABSTRACT

Methods, systems, and media for initiating and monitoring instances of workflows are provided. In some embodiments, the method comprises: retrieving, using a hardware processor, a workflow description that includes a plurality of steps and that corresponds to a group of simulations in a generative design system for generating a plurality of design iterations; generating, using the hardware processor, a graph that represents a workflow and that indicates interconnections between the plurality of steps; determining, using the hardware processor, information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps; determining, using the hardware processor, an execution strategy for performing the plurality of steps included in the workflow based on the determined information for the generative design system; causing, using the hardware processor, the generative design system to execute the plurality of steps in the workflow using the execution strategy; and updating, using the hardware processor, a user interface with one or more design iterations of the plurality of design iterations upon generation by the generative design system.

### CROSS-REFERENCE TO RELATED APPLICATIONS

This application claims the benefit of U.S. Provisional Patent Application No. 62/936,885, filed Nov. 18, 2019, which is hereby incorporated by reference herein in its entirety.

### TECHNICAL FIELD

The disclosed subject matter relates to methods, systems, and media for initiating and monitoring instances of workflows. More particularly, the disclosed subject matter relates to parameterizing, instantiating, and executing instances of workflows to simultaneously perform multiple design iterations in a computer-aided design application and to update a user interface as the design iterations are generated by the computer-aided design application.

### BACKGROUND

Computationally intensive simulations are frequently run for many purposes, such as architectural design, three-dimensional modeling, etc. Such simulations often require multiple iterations to generate a solution. For example, multiple iterations of a simulation might be run to execute a simulation with different parameters or inputs. As another example, multiple iterations of a simulation might be run as part of numerical modeling to iterate through a series of values (e.g., time points, etc.). However, such simulations can be computationally intensive and can cause a system or device running a simulation to lag or slow down. In such situations, it may be useful to divide a simulation into different iterations and have each iteration run on a different machine or a different virtual machine. However, it can be difficult to divide a simulation and aggregate information from different instances of a simulation.

Accordingly, it is desirable to provide new methods, systems, and media for initiating and monitoring instances of workflows.

### SUMMARY

Methods, systems, and media for initiating and monitoring instances of workflows are provided.

In accordance with some embodiments of the disclosed subject matter, a method for monitoring workflows for generating multiple design iterations is provided, the method comprising: retrieving, using a hardware processor, a workflow description that includes a plurality of steps and that corresponds to a group of simulations in a generative design system for generating a plurality of design iterations; generating, using the hardware processor, a graph that represents a workflow and that indicates interconnections between the plurality of steps; determining, using the hardware processor, information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps; determining, using the hardware processor, an execution strategy for performing the plurality of steps included in the workflow based on the determined information for the generative design system; causing, using the hardware processor, the generative design system to execute the plurality of steps in the workflow using the execution strategy; and updating, using the hardware processor, a user interface with one or more design iterations of the plurality of design iterations upon generation by the generative design system.

In some embodiments, generating the graph further comprises determining, based on the workflow description, that a first step in the workflow is to be performed prior to performing a second step in the workflow. In some embodiments, determining that an output value generated from the first step in the workflow is to be applied during execution of the second step in the workflow, wherein the information for the generative design system includes identifying a compatibility layer to communicate between the output value generated from the first step and the second step in the workflow.

In some embodiments, generating the graph further comprises determining, based on the workflow description, that a first step in the workflow and a second step in the workflow are to be executed concurrently.

In some embodiments, determining that the first subset of steps are to be batched together as the first batch based on a determination that there are no dependencies between steps in the first subset of steps.

In some embodiments, the information for the generative design system includes identifying resources required for each step in the workflow and determining that the first subset of steps are to be batched together as the first batch based on a determination that there are no resource conflicts between steps in the first subset of steps.

In some embodiments, the method further comprises determining that one or more virtual machine instances are to be generated to execute a portion of the workflow.

In accordance with some embodiments of the disclosed subject matter, a system for monitoring workflows for generating multiple design iterations is provided, the system comprising a memory and a hardware processor that, when configured to execute computer executable instructions stored in the memory, is configured to: retrieve a workflow description that includes a plurality of steps and that corresponds to a group of simulations in a generative design system for generating a plurality of design iterations; generate a graph that represents a workflow and that indicates interconnections between the plurality of steps; determine information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps; determine an execution strategy for performing the plurality of steps included in the workflow based on the determined information for the generative design system; cause the generative design system to execute the plurality of steps in the workflow using the execution strategy; and update a user interface with one or more design iterations of the plurality of design iterations upon generation by the generative design system.

In accordance with some embodiments of the disclosed subject matter, a non-transitory computer-readable medium containing computer executable instructions that, when executed by a hardware processor, cause the hardware processor to perform a method for monitoring workflows for generating multiple design iterations is provided, the method comprising: retrieving, using the hardware processor, a workflow description that includes a plurality of steps and that corresponds to a group of simulations in a generative design system for generating a plurality of design iterations; generating, using the hardware processor, a graph that represents a workflow and that indicates interconnections between the plurality of steps; determining, using the hardware processor, information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps; determining, using the hardware processor, an execution strategy for performing the plurality of steps included in the workflow based on the determined information for the generative design system; causing, using the hardware processor, the generative design system to execute the plurality of steps in the workflow using the execution strategy; and updating, using the hardware processor, a user interface with one or more design iterations of the plurality of design iterations upon generation by the generative design system.

In accordance with some embodiments of the disclosed subject matter, a system for monitoring workflows for generating multiple design iterations is provided, the system comprising: means for retrieving a workflow description that includes a plurality of steps and that corresponds to a group of simulations in a generative design system for generating a plurality of design iterations; means for generating a graph that represents a workflow and that indicates interconnections between the plurality of steps; means for determining information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps; means for determining an execution strategy for performing the plurality of steps included in the workflow based on the determined information for the generative design system; means for causing the generative design system to execute the plurality of steps in the workflow using the execution strategy; and means for updating a user interface with one or more design iterations of the plurality of design iterations upon generation by the generative design system.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements.

FIG. 1 shows an example of a process for initiating and monitoring instances of workflows to execute a simulation in accordance with some embodiments of the disclosed subject matter.

FIG. 2 shows an example of a schematic diagram for generating and managing virtual machine instances to execute a simulation in accordance with some embodiments of the disclosed subject matter.

FIG. 3 shows a schematic diagram of an illustrative system suitable for implementation of mechanisms described herein for initiating and monitoring instances of workflows in accordance with some embodiments of the disclosed subject matter.

FIG. 4 shows a detailed example of hardware that can be used in a server and/or a user device of FIG. 3 in accordance with some embodiments of the disclosed subject matter.

### DETAILED DESCRIPTION

In accordance with various embodiments, mechanisms (which can include methods, systems, and media) for initiating and monitoring instances of workflows are provided.

In some embodiments, the mechanisms described herein can be used to automate execution of a workflow that includes multiple steps, processes, or simulations. For example, in some embodiments, the techniques described herein can be used to automate execution of a workflow that includes multiple steps, processes, or simulations, and where results of a first step, process, or simulation are used during execution of a second step, process, or simulation. Additionally, in some embodiments, the techniques described herein can be used to automate execution of a workflow that includes multiple steps, processes, or simulations that each use different hardware or software resources. For example, in an instance in which a workflow includes multiple steps, processes, or simulations, and where one or more simulations utilize particular software libraries that are to be executed on particular environmental resources (e.g., using public cloud computing resources, using virtualized machines, and/or any other suitable resources), the techniques described herein can be used to acquire required resources, relinquish resources when a step or process utilizing the resource has terminated, acquire credentials or licenses required to use a particular resource (e.g., a license to use a particular software library, etc.), and/or perform any other suitable functions across steps or processes that each use different resources.

In some embodiments, the mechanisms described herein can interface between connected steps or processes. For example, in some embodiments, the mechanisms can format output values generated by a first step, process, or simulation that are to be used by a second step, process, or simulation to be in a format required by the second step, process, or simulation. In another example, in some embodiments, the mechanisms can convert between file formats to ensure that the output of a step, process, or simulation can be processed by a subsequent step, process, or simulation as input.

In some embodiments, the mechanisms described herein can generate an execution strategy for a workflow that includes multiple steps that indicates any suitable information, such as an order in which steps or processes of the workflow are to be executed, optimal computing resources to be used to execute each step or process (e.g., to minimize cost, to minimize runtime, and/or to optimize any other suitable criteria), licenses or other credentials that are to be acquired at particular times, and/or any other suitable information. In some embodiments, the mechanisms can then cause the workflow to be executed in an automated manner based on the execution strategy. For example, in an instance in which a first step or process in a workflow generates one or more values that are to be used by a second step or process in the workflow, the mechanisms described herein can cause the first step or process to be executed prior to initiation of the second step or process. As another example, in some embodiments, the mechanisms described herein can determine that two steps or processes included in a workflow do not share any dependencies and/or that the two steps or processes do not require the same computing resources, and the mechanisms can therefore determine that the two steps or processes can be executed concurrently and/or in parallel.

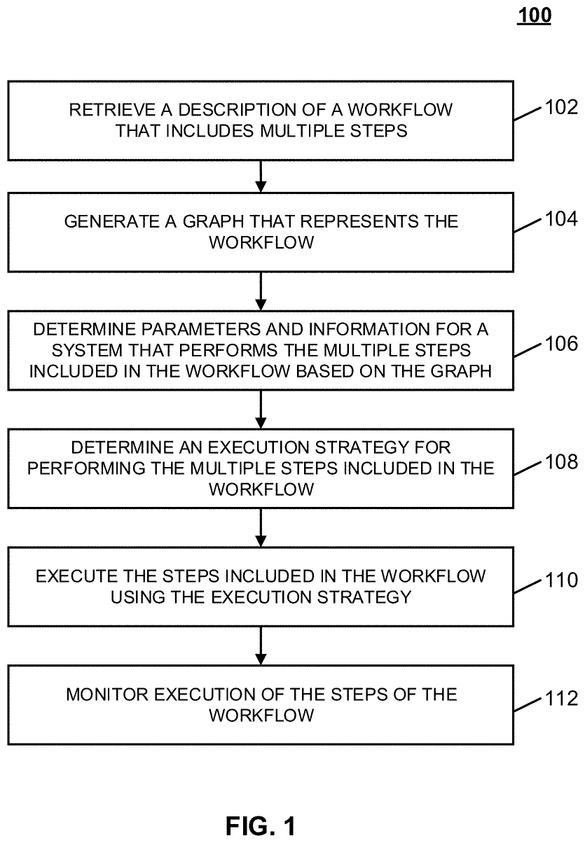

In some embodiments, the mechanisms described herein can monitor execution of the steps or processes included in a workflow and can provide progress updates to a user executing the workflow and/or any suitable process or system in any suitable manner. For example, as described below in connection with FIG. 1, in some embodiments, the mechanisms can provide progress updates via a user interface. As another example, in some embodiments, the mechanisms can update a log file associated with execution of the workflow. In some embodiments, the progress updates can include any suitable information, such as runtimes of different steps included in the workflow, intermediate values generated by a particular step or process, and/or any other suitable information.

Additionally, in some embodiments, the mechanisms described herein can handle errors generated by a step in a series of steps included in a workflow by identifying an action to be taken to allow the workflow to continue. For example, in an instance in which an error is generated during execution of a first step in a series of steps, the mechanisms described herein can identify one or more actions to be taken in response to the generated error, thereby allowing execution of the series of steps in the workflow to continue. As a more particular example, in some embodiments, the mechanisms described herein can determine an alternative operation to be executed in response to determining that a primary operation has generated an error.

Note that, in some embodiments, the techniques described herein can be used for simulations that use any suitable type of software, simulation packages, workflows, etc., or any combination of software, simulation packages, workflows, etc. In some embodiments, the mechanisms described herein can transition between different packages or workflows automatically. For example, in some embodiments, in an instance in which a first package is used for a first portion of a simulation and in which a second package is used for a second portion of a simulation, the mechanisms described herein can automatically transition between the first package and the second package. In some such embodiments, any suitable plugins can be installed for each package to allow the mechanisms to automatically transition between packages or workflows.

Turning to FIG. 1, an example 100 of a process for initiating and monitoring instances of workflows is shown in accordance with some embodiments of the disclosed subject matter. In some embodiments, blocks of process 100 can be executed on any suitable device, such as a user device running a simulation, and/or any other suitable device.

At 102, process 100 can begin by retrieving a description of a workflow that includes multiple steps. In some embodiments, the workflow can correspond to any suitable process or group of processes. For example, in some embodiments, the workflow can correspond to a simulation or a group of simulations, which can, in some embodiments, include any suitable number of blocks or iterations. As a more particular example, in some embodiments, the workflow can correspond to any suitable type(s) of simulations, such as urban design simulations, architectural simulations, computer-aided design simulations, numerical modeling, and/or any other suitable type of simulation(s). Additionally, in some embodiments, in instances in which the workflow includes multiple simulations, one or more outputs or intermediate parameters generated by a first simulation can be used during execution of a second simulation. Note that, as described below in more detail in connection with blocks 106 and 108, in some embodiments, a simulation or a step included in the workflow can be executed by any suitable software, software package, modeling package, etc.

In some embodiments, process 102 can retrieve the description of the workflow in response to any suitable information or user input. For example, in some embodiments, the description of the workflow can be included in any suitable type of file(s) of any suitable format, and the description of the workflow can be retrieved in response to receiving a user input to open the file(s) associated with the description of the workflow. As another example, in some embodiments, the description of the workflow can be retrieved in response to process 100 receiving a user input that indicates that a user of a user device is initiating the workflow. In some embodiments, the user input can include any suitable command that causes the workflow to be initiated (e.g., a command entered via selection of a selectable input of a user interface, a command entered via a command prompt, and/or any other suitable type of command).

In some embodiments, the description of the workflow can have any suitable format. For example, in some embodiments, the description of the workflow can include a set of classes in any suitable programming or scripting language (e.g., Python, and/or any other suitable language). In some embodiments, each class can represent actions that can be taken on a group of inputs, parameterizations of each input in the group of inputs, and/or any other suitable information. Note that, in some embodiments, a description can itself be valid (i.e., executable) code. As another example, in some embodiments, the description of the workflow can include a graph that indicates a manner in which steps of the workflow are connected. Note that a more detailed description of a graphical representation of the workflow is described below in connection with block 104. As yet another example, in some embodiments, the description of the workflow can include lists of inputs and/or outputs. In some such embodiments, process 100 can identify processes or simulations that are to be executed to generate the required inputs and/or outputs.

In some embodiments, the description of the workflow can include any suitable information indicating sequences of steps included in the workflow, and/or any other suitable information. For example, in some embodiments, the description of the workflow can indicate an order in which steps or simulations are to be performed or an order in which steps or simulations can be performed. As a more particular example, in some embodiments, the description can indicate that a first step must be performed prior to a second step. As a more specific example, in some embodiments, the description can indicate that the first step must be performed prior to the second step and that an output value or an intermediate value generated during execution of the first step is to be used during execution of the second step. As another more particular example, in some embodiments, the description can indicate that a first step and a second step can be performed concurrently. As yet another more particular example, in some embodiments, the description can indicate a number of iterations that are to be performed for a particular step. As still another more particular example, in some embodiments, the description can indicate one or more stopping criteria for a particular step. As still another example, in some embodiments, the description of the workflow can include one or more choices or decision points. As a more particular example, in some embodiments, the description of the workflow can indicate that a decision is to be made, after execution of a first step, which of a second step or a third step is to be executed. Continuing with this example, the description of the workflow can include any suitable criteria or information upon which the decision is to be made, such as whether the decision is to be made manually (e.g., that execution of the workflow is to be paused until a user input is received), criteria that are to be algorithmically evaluated (e.g., that the second step is to be executed in response to an output value associated with the first step being within a particular range of values, that the third step is to be executed in response to an output value associated with the first step exceeding a predetermined threshold, and/or any other suitable criteria), and/or any other suitable information.

Note that, in some embodiments, the description of the workflow can be generated in any suitable manner. For example, in an instance in which the description of the workflow includes a set of classes in a particular language (e.g., Python, and/or any other suitable language), the description of the workflow can be generated as a text file or any other suitable file that includes source code for the set of classes. As another example, in some embodiments, the description of the workflow can be generated using any suitable user interface. As a more particular example, in some embodiments, the user interface can be used to add and/or arrange the steps included in the workflow (e.g., to specify an order of steps, to specify inputs and/or outputs of each step, etc.) in any suitable manner (e.g., by dragging and dropping indications of steps, and/or in any other suitable manner). Continuing with this example, in some embodiments, the description of the workflow can then be generated based on the information received by the user interface. As a more particular example, in some embodiments, in instances in which the description of the workflow includes a set of classes, the set of classes can be generated based on information received by the user interface. As another more particular example, in some embodiments, in instances in which the description of the workflow includes a graphical representation of the workflow, the graphical representation can be generated based on information received by the user interface.

At 104, process 100 can generate a graph that represents the workflow based on the description of the workflow. Note that, in instances in which the description of the workflow retrieved at block 102 is a graphical representation of the workflow, block 104 can be omitted.

In some embodiments, the graph that represents that workflow can include any suitable information. For example, in some embodiments, the graph can indicate a required or optional sequence of the steps of the workflow that are to be performed. As a more particular example, in some embodiments, the graph can indicate that a first step of the workflow must be performed prior to execution of a second step of the workflow. As another more particular example, in some embodiments, the graph can indicate that a first step of the workflow and a second step of the workflow can be performed concurrently. As another example, in some embodiments, the graph can indicate that an output value generated by a first step or simulation is to be used as an input value by a second step or simulation. As yet another example, in some embodiments, the graph can indicate that a particular input value is to be determined based on a user input during execution of the workflow. As still another example, in some embodiments, the graph can indicate one or more decision points during execution of the workflow. As a more particular example, in some embodiments, the graph can indicate that a first step or simulation is to be executed in response to particular criteria being met, or, alternatively, that a second step or simulation is to be executed in response to the particular criteria not being met.

At 106, process 100 can determine parameters and information for a system that performs the multiple steps included in the workflow based on the graph. In some embodiments, the parameters and information can include any suitable information about the steps, processes, or simulations included in the workflow. For example, in some embodiments, process 100 can determine scheduling of multiple steps or processes included in the workflow, such as whether a first step must precede a second step because the first step generates a value that is to be used by the second step, whether two steps can be executed concurrently, and/or any other suitable scheduling information. As another example, in some embodiments, process 100 can determine that a group of steps or processes can be batched and can therefore be executed as a group. In some such embodiments, process 100 can determine that the group of steps or processes can be batched based on any suitable information, such as that there are no dependencies between the steps or processes in the group of steps or processes, that there are no hardware or software conflicts between the steps or processes in the group of steps or processes, and/or based on any other suitable information.

As still another example, in some embodiments, process 100 can identify resources required for each step or process included in the workflow. As a more particular example, in some embodiments, process 100 can identify hardware requirements of each step or process, such as a number or type of different hardware components (e.g., GPUs, FPGAs, RAM, CPU cores, etc.). As another more particular example, in some embodiments, process 100 can identify requirements associated with software libraries or packages used by each step or process in the workflow, such as: operating systems a particular library or package is to be run on; licenses required to use a particular library or package; third-party credentials required to access a particular database, library, or package; information relating to memory or storage used by different libraries or packages (e.g., whether data used by a particular library is stored in local memory of a device or in a cloud, permissions required for usage of a cloud by a library, an amount of memory required by a particular library or package, and/or any other suitable information); and/or any other suitable requirements. As yet another more particular example, in some embodiments, process 100 can identify network information associated with executing steps or processes in the workflow, such as identifying networks or virtual networks associated with different steps or processes, determining firewall rules, and/or any other suitable network information. As still another more particular example, in some embodiments, process 100 can identify logistical infrastructure information, such as queue information (e.g., Pub Sub queues, and/or any other suitable type of queues).

In some embodiments, the information determined by process 100 can include potential states of the system executing the steps of the workflow. For example, in some embodiments, process 100 can identify a state Sin which a particular group of files or output values have been generated by one or more steps or processes. Continuing with this example, in some embodiments, process 100 can determine that a response to the system being in state S is that a second step or process can be initiated because the second step or process requires the group of files or output values corresponding to state S. As another example, in some embodiments, process 100 can identify a state S′ in which a subset of files or output values have been generated by one or more steps or processes, and that a response to the system being in state S′ is to initiate a second step or process that is associated with a relatively long initialization process, thereby allowing the second step or process to begin initialization prior to all required inputs or parameters being available.

Note that, in some embodiments, process 100 can identify any suitable compatibility layers required for two steps or processes to communicate or otherwise interoperate. For example, in some embodiments, process 100 can determine that a second step that takes, as an input, a value that is generated during execution of a first step, requires that the value be in a particular format. Continuing with this example, in some embodiments, process 100 can determine that a compatibility layer that interfaces between the first step and the second step is required to re-format the value to the particular format required by the second step or process. As another example, in some embodiments, process 100 can identify any suitable standards that indicate a format or manner in which different steps or processes included in the workflow are to interface or communicate. Note that, in some embodiments, compatibility layers can include any suitable services, such as a service for notifying a user of events, a service for interacting with a global database that stores values from multiple steps or processes, a storage interface for interacting with multiple cloud storage services, logging or debugging services for logging and tracking errors thrown by multiple steps or processes, and/or any other suitable services used by multiple steps or processes included in the workflow.

In instances in which the workflow includes one or more simulations, note that, in some embodiments, a simulation can be run using any suitable software, software package, modeling package, and/or in any other suitable manner. For example, in some embodiments, the simulation can be associated with a particular simulation environment, such as an environment for three-dimensional modeling or simulations, and/or any other suitable environment. Additionally, note that, in some embodiments, a simulation can be associated with multiple blocks or iterations. For example, in some embodiments, a simulation can be associated with multiple iterations, each iteration associated with different values of one or more parameters of the simulation. As a more particular example, in some embodiments, each iteration can be associated with a different time step. As another more particular example, in some embodiments, each iteration can be associated with a different value of a parameter from a group of values associated with that parameter. As another example, in some embodiments, a simulation can be associated with multiple blocks, such as calls to different functions, and/or any other suitable type of block. As yet another example, in some embodiments, a simulation can include one or more loops of a block of code. Note that, as described herein, an iteration can correspond to a full run of a simulation, a run of a portion or subset of a simulation, a block or portion of a simulation, a loop or multiple loops of a portion of a simulation, and/or any other suitable chunk or portion of a simulation. In some embodiments, a second iteration of a simulation may depend on results from a first iteration of the simulation. Alternatively, in some embodiments, each iteration can be independent of other iterations of the simulation.

At 108, process 100 can determine an execution strategy for performing the multiple steps included in the workflow. In some embodiments, determining the execution strategy can include obtaining a group of executable resources required to execute the steps or processes included in the workflow. For example, in some embodiments, process 100 can identify, initialize, and/or instantiate any suitable containers (e.g., Docker containers, and/or any other suitable containers), any suitable Function as a Service (FaaS) infrastructure (e.g., functions performed using any suitable cloud services, and/or any other suitable FaaS infrastructure), virtualized or non-virtualized computers (e.g., local computing devices, remote computing devices, private cloud devices, a public cloud environment, and/or any other suitable computing device(s)), and/or any other suitable devices, components, or infrastructure. Note that, in some embodiments, process 100 can identify and instantiate resources based on any suitable information or criteria, such as cost required for different resources, historical performance associated with different candidates for a resource, and/or any other suitable information. Additionally, note that, in some embodiments, process 100 can identify and instantiate potential candidate resources (e.g., a particular virtualized machine, a particular remote computing device, and/or any other suitable resource) to optimize any suitable criteria or tradeoffs between criteria. For example, in some embodiments, process 100 can identify and instantiate resources to minimize a total cost. As another example, in some embodiments, process 100 can identify and instantiate resources to minimize a speed of workflow execution. As another particular example, in some embodiments, process 100 can identify and instantiate resources to minimize a speed of a particular step or process of the workflow while minimizing a cost associated with execution of a different step or process of the workflow.

As another example, in some embodiments, process 100 can execute any suitable scripts, configurations, or commands to require infrastructure or resources to be used during execution of steps or processes included in the workflow. As a more particular example, in some embodiments, process 100 can generate any suitable machine images. As another more particular example, in some embodiments, process 100 can execute any suitable scripts to configure a firewall. As yet another more particular example, in some embodiments, process 100 can execute any suitable scripts for machine startup or for automated installation of particular software packages. As still another more particular example, in some embodiments, process 100 can execute any suitable scripts or commands for management and/or allocation of software licenses required by any steps or processes included in the workflow. As still another more particular example, in some embodiments, process 100 can execute any suitable scripts or commands for configuring any suitable software packages to be used by any of the steps or processes included in the workflow. As still another more particular example, in some embodiments, process 100 can execute any suitable scripts or commands for acquiring credentials for accessing services to be used by any of the steps or processes included in the workflow.

As yet another example, in some embodiments, process 100 can determine that one or more new virtual machine instances are to be generated to execute any suitable portions of the workflow (e.g., one or more iterations of a simulation included in the workflow, one or more steps or processes included in the workflow, and/or any other suitable portions of the workflow). In some embodiments, process 100 can determine that the one or more new virtual machine instances are to be generated based on any suitable information. As a more particular example, in some embodiments, process 100 can determine that the one or more new virtual machine instances are to be generated based on information associated with a simulation or process included in the workflow, such as a complexity of the simulation or process. As a specific example, in some embodiments, process 100 can determine that the one or more new virtual machine instances are to be generated based on a simulation including more than a predetermined number of iterations, more than a predetermined number of loops of a particular portion of the simulation, etc. (e.g., more than ten loops, more than ten calls to a particular function, and/or any other suitable information). As another specific example, in some embodiments, process 100 can determine that the one or more new virtual machine instances are to be generated based on information indicating that a simulation is to be run more than a predetermined number of times (e.g., more than ten times, more than twenty times, and/or any other suitable number), such as to run the simulation with multiple values of a particular parameter and/or to determine an average result of the simulation.

As another more particular example, in some embodiments, process 100 can determine that the one or more new virtual machine instances are to be generated based on a current performance of the device executing a simulation. As a specific example, in some embodiments, process 100 can determine that the one or more new virtual machine instances are to be generated in response to determining that a current performance of the device executing the simulation has dropped below a predetermined threshold with respect to any suitable performance metric. More particularly, in some embodiments, process 100 can determine that the one or more new virtual machine instances are to be generated in response to determining that a duration of time required to execute a particular portion of the simulation has exceeded a predetermined threshold (e.g., a particular loop has taken longer than ten seconds to execute, a particular function call has taken longer than ten seconds to execute, and/or any other suitable threshold).

As yet another more particular example, in some embodiments, process 100 can determine that the one or more new virtual machine instances are to be generated based on an increase in speed that would occur from the one or more new virtual machine instances (e.g., a performance of a device executing a simulation, an overall processing speed, etc.), if used, and a cost that would be incurred from the one or more new virtual machine instances (e.g., a cloud computing cost). As a specific example, in some embodiments, process 100 can determine whether the increase in speed exceeds a predetermined threshold based on the cost that would be incurred. More particularly, in some embodiments, process 100 can determine whether a ratio of the increase in speed to the cost exceeds a predetermined threshold. In some embodiments, process 100 can use any other suitable metric to balance an increase in speed from use of one or more virtual machine instances with the cost of the one or more virtual instances.

At 110, process 100 can execute the steps or processes included in the workflow using the execution strategy. In some embodiments, process 100 can execute the steps or processes included in the workflow in any suitable manner. For example, in some embodiments, based on the execution strategy, process 100 can initiate or launch two processes that have been indicated as acceptable to execute concurrently. As another example, in some embodiments, process 100 can cause a first process to be initiated or launched and can cause a second process to be inhibited from execution based on a determination that the second process requires data to be generated by the first process. Note that, as described above, in some embodiments, in instances in which two processes are executed concurrently, process 100 can cause the concurrent execution to be performed in any suitable manner, such as on two different physical devices, on two different virtual machines, using two threads on the same physical device, etc.

In some embodiments, process 100 can revise resources during execution of steps or processes of the workflow in any suitable manner. For example, in an instance where a first process requires particular resources (e.g., access to a particular database, access to a particular software library, access to a particular public computing resource, and/or any other suitable resources), process 100 can cause the resource to be relinquished in response to determining that the first process has finished execution and/or has finished any blocks that use the resource. As a more particular example, in an instance in which a step or process uses a particular software library that requires a license, process 100 can cause the license to be relinquished in response to determining that the step or process has completed and/or in response to determining that the step or process has finished a block of code that requires the software library.

Note that, in some embodiments, process 100 can instantiate inputs for different steps or processes included in the workflow in any suitable manner. For example, in some embodiments, process 100 can instantiate any suitable group of inputs using randomized values that are seeded in any suitable manner. As another example, in some embodiments, process 100 can instantiate inputs by executing any suitable optimization algorithm to select an optimal initial value for a particular input value. Note that, in some embodiments, process 100 can modify an initial value for a particular input value to iteratively more optimal initial values by using feedback over multiple iterations of the workflow. For example, in an instance in which an initial value for an input value is randomly selected during a first set of iterations of the workflow (e.g., during the first ten iterations, during the first hundred iterations, and/or any other suitable number), process 100 can select a more optimal initial value for the input value based on any suitable performance metrics associated with the step or process during the first set of iterations. As a more particular example, in some embodiments, process 100 can select a more optimal initial value based on an initial value that was associated with a decreased time to convergence or decreased time to meet a stopping criteria during the first set of iterations. Additionally, note that, in some embodiments, process 100 can provide any suitable options to re-run selected portions of the workflow any suitable number of times or over any suitable number of iterations, for example, to identify optimal values for any suitable input values or parameters. In some such embodiments, the selected portions of the workflow can be executed the indicated number of times subject to any suitable optimization criteria (e.g., to minimize a cost, to minimize a runtime, to minimize a number of iterations until a stopping criteria is reached, and/or any other suitable criteria).

In some embodiments, process 100 can perform any suitable termination procedures for a step or process in response to determining that the step or process has completed. For example, in some embodiments, the termination procedures can include relinquishing resources used by the step or process (as described above), formatting one or more outputs by the step or process into a format used as an input by a second step or process, and/or performing any other suitable termination procedures. Note that, in some embodiments, a termination procedure for a particular step or process included in the workflow can be determined or retrieved in any suitable manner. For example, in some embodiments, a termination procedure for a particular step or process can be specified in the description of the workflow retrieved at block 102.

Note that, in some embodiments, execution of a particular step or process included in the workflow can include interacting with a software application in a manner similar to a human user. For example, in some embodiments, a step or process can use a software application that provides a graphical user interface, where the software application does not expose functionality in any other manner suitable for automated interaction. In some such embodiments, process 100 can use any suitable automation technique(s) (e.g., inter-process communication, COM, APIs, embedding, command line usage, and/or any other suitable technique(s)). Additionally, in some embodiments, process 100 can use any suitable techniques to interact with a user interface in an automated manner. For example, in some embodiments, process 100 can use any suitable computer vision or text analysis technique(s) to determine a state of a user interface at a particular time point (e.g., to identify text fields that are to be filled in, and/or to determine any other state information). As another example, in some embodiments, process 100 can use software generated user input events, playback of recorded user actions, runtime instrumentation or hooking, and/or any other suitable technique(s) to interact with a user interface in an automated manner. In some embodiments, process 100 can perform any suitable tasks using the automation techniques described above, such as opening files, running commands, modifying data structures, setting parameters, detecting and reading desired outputs, storing outputs, and/or any other suitable tasks. Note that, in some embodiments, process 100 can perform any suitable pre-processing and/or post-processing during automated performance of tasks, for example, to integrate a step with other steps included in the workflow.

Additionally, note that, in some embodiments, process 100 can identify any suitable supplemental functions that are required by a particular step or process, and can cause the supplemental functions to be executed. For example, in an instance in which, during execution of a particular step, a document which contains placeholder values is opened, process 100 can determine any suitable replacements for the placeholder values (e.g., by analyzing the document and/or the placeholder values), and can cause the placeholder values to be replaced prior to continuing execution of the step.

In some embodiments, process 100 can execute particular software with any suitable instrumentation applied (e.g., debuggers, API call tracers, and/or any other suitable instrumentation). In some such embodiments, the instrumentation can indicate information about execution of a step that uses the software, information available to the software internally, and/or any other suitable information. Additionally, in some embodiments, such instrumentation can provide an ability to modify portions of application execution, for example, to run computationally heavy tasks on lower cost machines, and/or any other suitable modifications.

Note that, in instances in which process 100 determined at block 108 that one or more new virtual machine instances are to be instantiated to execute the workflow, process 100 can generate the one or more new virtual machine instances in any suitable manner. For example, in some embodiments, process 100 can transmit instructions to a server that hosts the one or more virtual machine instances. In some such embodiments, the server can be associated with any suitable Infrastructure as a Service (IaaS) entity, and/or any other suitable entity. In some embodiments, instructions to generate the one or more new virtual machine instances can include any suitable information, such as a number of CPUs to be associated with each virtual machine instance, an amount of memory to be associated with each virtual machine instance, and/or any other suitable information.

Additionally, in instances in which one or more new virtual machine instances are generated to execute portions of the workflow, process 100 can transmit information related to the portions of the workflow to the new virtual machine instance(s) in any suitable manner. For example, in some embodiments, process 100 can transmit information related to a software environment in which a process or simulation is being executed that causes the software environment to be opened or initialized. As another example, in some embodiments, process 100 can transmit information related to a simulation, such as values of parameters or variables required to execute an iteration of the simulation on the new virtual machine instance(s). As yet another example, in some embodiments, process 100 can transmit any suitable code or information that indicates commands corresponding to an iteration of a simulation to be executed by a particular virtual machine instance. As a more particular example, in an instance in which the iteration corresponds to a loop of a portion of code of the simulation, process 100 can transmit the portion of code to the virtual machine instance. As another more particular example, in an instance where the iteration corresponds to a call to a particular function, process 100 can transmit code associated with the function, input arguments associated with the function, and/or any other suitable information.

Note that, in instances in which a single virtual machine instance executes multiple iterations of a process or simulation, the multiple iterations can be grouped together on the virtual machine instance in any suitable manner. For example, in some embodiments, the multiple iterations can each be associated with a common identifier in association with the virtual machine instance on which the iterations are executed. In some such embodiments, the common identifier can be assigned by process 100. In some embodiments, process 100 can determine whether the multiple iterations are to be grouped based on any suitable information. For example, in some embodiments, process 100 can determine that the multiple iterations are to be grouped based on a determination that a result of one iteration is an input to another iteration. As another example, in some embodiments, process 100 can determine that the multiple iterations are to be grouped based on a determination that each iteration shares a common block (e.g., a common block of code corresponding to a particular calculation, and/or any other suitable common block), and that grouping the iterations would allow the virtual machine instance to execute the common block once and share a result of the common block across all iterations.

At 112, process 100 can monitor execution of the steps of the workflow. In some embodiments, process 100 can provide any suitable information regarding progress or status of steps or processes included in the workflow in any suitable manner. For example, in some embodiments, process 100 can provide updates indicating progress or status in a user interface presented on a user device that initiated execution of the workflow. As another example, in some embodiments, process 100 can update a file or multiple files that include a log associated with execution of the workflow. As still another example, in some embodiments, process 100 can be configured to alert another user device based on performance during execution of the steps of the workflow (e.g., a client device requesting execution of the workflow) in any suitable manner, such as via an API, via email, via FTP, and/or in any other suitable manner.

In some embodiments, the updates indicating progress or status can include any suitable information, such as a duration of time elapsed during execution of a particular step or process included in the workflow, whether any errors or exceptions were thrown during execution of a particular step or process, values generated by a step or process (e.g., a value designated as important, and/or any other suitable value), timestamps at which particular processes were initiated or particular functions were called, timestamps at which particular resources were acquired and/or relinquished, and/or any other suitable progress or status information. Note that, in some embodiments, process 100 can perform any suitable clustering of performance metrics across iterations of a step or process. For example, in an instance in which a particular step, process, or simulation is executed for a predetermined number of iterations (e.g., one hundred iterations, one thousand iterations, and/or any other suitable number), process 100 can perform any suitable calculations on performance metrics associated with each iteration of the step or process and can present aggregated metrics to a user. As a more particular example, process 100 can perform t-distributed Stochastic Neighbor Embedding (T-SNE) clustering on any suitable performance metrics across multiple iterations of a step, process, or simulation. As another more particular example, in some embodiments, process 100 can calculate a mean or median of any suitable performance metric (e.g., a runtime for a step or process, and/or any other suitable metric).

In some embodiments, during monitoring of execution of the steps of the workflow, process 100 can identify an error and can identify an action in response to the error. For example, in some embodiments, process 100 can determine that the operation that generated the error is to be re-tried a predetermined number of times (e.g., two more times, three more times, and/or any other suitable number of times). As another example, in some embodiments, process 100 can identify an alternative operation that is to be executed and can cause the alternative operation to be executed. Note that, in some embodiments, process 100 can identify actions to be performed in response to determining that an error has been generated for a particular operation in any suitable manner. For example, in some embodiments, process 100 can access a list or lookup table that indicates actions to be performed for different types of errors. As a more particular example, in some embodiments, process 100 can determine that a response to a timeout error is to include re-trying the operation that timed out a predetermined number of times. As another more particular example, in some embodiments, process 100 can determine that a response to an error that indicates that access was not granted to a particular resource is to include accessing credentials or other authorization to access the particular resource.

Note that, in instances in which process 100 generated one or more virtual machine instances to execute portions of the workflow, process 100 can receive information from the one or more virtual machine instances. For example, in some embodiments, process 100 can receive results from an iteration of a step, process, or simulation executed on each virtual machine instance. As another example, in some embodiments, process 100 can receive intermediate results from intermediate blocks of an iteration executing on each virtual machine instance. Note that, in instances in which multiple virtual machine instances have been generated, process 100 can receive information from each virtual machine instance in any suitable order and at any suitable times. In some embodiments, process 100 can combine information received from each of the one or more virtual machine instances and can present the combined information. In some embodiments, process 100 can combine the information received from each of the one or more virtual machine instances in any suitable manner. For example, in some embodiments, code or other instructions associated with the step, process, or simulation can indicate a manner in which results from different iterations are to be combined (e.g., as a sum, as a weighted average, as a product, and/or in any other suitable manner), and process 100 can combine the results from each iteration executed on each virtual machine instance based on the code or other instructions associated with the step, process, or simulation. In some embodiments, process 100 can present the combined information in any suitable manner. For example, in some embodiments, the combined information can correspond to a final result of a simulation, and process 100 can cause the final result of the simulation to be presented (e.g., in a user interface, and/or in any other suitable manner). As another example, in some embodiments, the combined information can correspond to an intermediate value of the simulation, and process 100 can cause the intermediate value to be presented (e.g., in a user interface, and/or in any other suitable manner). In some such embodiments, process 100 can update the presented information as additional information is received from the one or more virtual machine instances. For example, in some embodiments, process 100 can receive updated information from each of the virtual machine instances, and process 100 can then update the intermediate value and present updated combined information.

Additionally, note that, in some embodiments, the received information can indicate any suitable information related to operation of the virtual machine instance and/or related to execution of the iteration on the virtual machine instance. For example, in some embodiments, the received information can indicate a speed with which blocks of an iteration are being executed on a virtual machine instance (e.g., that a particular loop executed in ten seconds, and/or any other suitable speed information). As another example, in some embodiments, the received information can indicate errors that occurred during execution of an iteration on a particular virtual machine instance. Note that, in instances where the received information indicates an error that occurred during execution of an iteration on a virtual machine instance, process 100 can transmit any suitable updated instructions to the virtual machine instance to allow the virtual machine instance to re-execute the iteration (e.g., an updated parameter or variable values, updated code or instructions corresponding to the iteration, and/or any other suitable updated instructions).

Note that, in some embodiments, output values generated by particular steps or processes included in the workflow can be designated as output values that are to be provided to a user in any suitable manner. For example, in an instance in which the workflow includes one or more simulations, results of the one or more simulations can be designated as output values that are to be provided in any suitable manner (e.g., in a user interface presented on a user device, written to an output log file, and/or in any other suitable manner). Note that, in some embodiments, output values can include any suitable type of content or result, such as a numeric value, text, one or more graphs, a decision generated as a result of one or more processes included in the workflow, a prediction or a classification generated as a result of one or more processes or simulations included in the workflow, and/or any other suitable type of content.

Note that, in some embodiments, process 100 can monitor execution of a particular step or process in any suitable manner. For example, in some embodiments, process 100 can access any suitable computation resources used (e.g., via SSH, and/or in any other suitable manner), via execution of a program associated with the step or process (e.g., via a debugger, by tracing a system call, and/or in any other suitable manner), and/or in any other suitable manner. As another example, in some embodiments, process 100 can indirectly monitor execution of a step or process in any suitable manner. For example, in some embodiments, process 100 can access logs or files associated with any suitable infrastructure or services used by steps or processes included in the workflow and can infer any suitable performance metrics from the accessed logs or files (e.g., a runtime of a particular process, and/or any other suitable performance information).

Additionally, note that, in some embodiments, process 100 can collect or measure any suitable performance information across multiple steps or processes. For example, in some embodiments, process 100 can collect or measure a duration of time required to execute two steps or processes that are frequently run in succession. As another example, in some embodiments, process 100 can calculate an average cost to perform a particular step or process or to perform a group of steps or process. Note that, in some embodiments, any suitable cost information can be output to a different file than a file used to collect other performance metrics, for example, to generate an invoice or other billing document.

Note that, in some embodiments, any portions of blocks of process 100 can be executed by a distributed system using any suitable technique(s). For example, in some embodiments, process 100 can use consensus algorithms, message passing, callbacks, peer-to-peer systems, and/or any other suitable techniques to execute steps or processes of a workflow in a distributed system. In some embodiments, a distributed system can delegate portions of functionality to any suitable separate processes, for example, to ensure reliability, to reduce risks due to single-component failure, and/or for any other suitable purpose.

In some embodiments, steps or processes included in a workflow can be exposed via an Application Programming Interface (API), which can allow for interaction with the steps or processes (e.g., to provide parameters, view results of steps or processes, and/or for any other suitable purpose). For example, in some embodiments, a request to view a particular value computed by a step or process included in the parameter can be received by an API associated with the step or process. Continuing with this example, in some embodiments, the API response can include the requested value. In some such embodiments, the API response can include any other suitable information, such as a list of parameters required to proceed (e.g., to proceed to a next step or process, to proceed within the same step or process, etc.). Continuing further with this example, in some embodiments, a second API call can then transmit the required parameters to allow execution within the workflow to continue. Note that, in some embodiments, an API can be used in connection with any suitable user interface, thereby allowing a user of a user device that presents the user interface to interact with a step or process associated with the API (e.g., to view computed values, to view generated errors, and/or any other suitable interactions).

Additionally, note that, in some embodiments, an API that is used in connection with a user interface to query performance of a step or process associated with the API can be associated with any suitable machine learning algorithm(s). In some such embodiments, the machine learning algorithm(s) can be trained to identify patterns or heuristics indicating human behavior associated with the step or process. For example, in some embodiments, the machine learning algorithm(s) can identify potential block points at which a user typically requests to view one or more intermediate value(s) computed by the step or process, a point at which an error is typically generated, and/or any other suitable information. In some such embodiments, information generated by the machine learning algorithm(s) associated with the API can then be used to improve performance of the corresponding step or process, thereby improving efficiencies and/or decreasing reliance on manual input or interaction.

Additionally, note that, in some embodiments, an API that is used in connection with a user interface to receive user input in connection with a step or process associated with the API can be associated with any suitable machine learning algorithm(s). For example, in some embodiments, the API can provide a user interface that requests that a user provide an input (e.g., a “YES” or “NO” decision on whether a building looks good to a user, a domain expert provides values based on judgement and/or experience, etc.). In continuing this example, the machine learning algorithm(s), trained using the received user input, can be used to automatically make similar decisions in subsequent steps or processes without requiring user intervention.

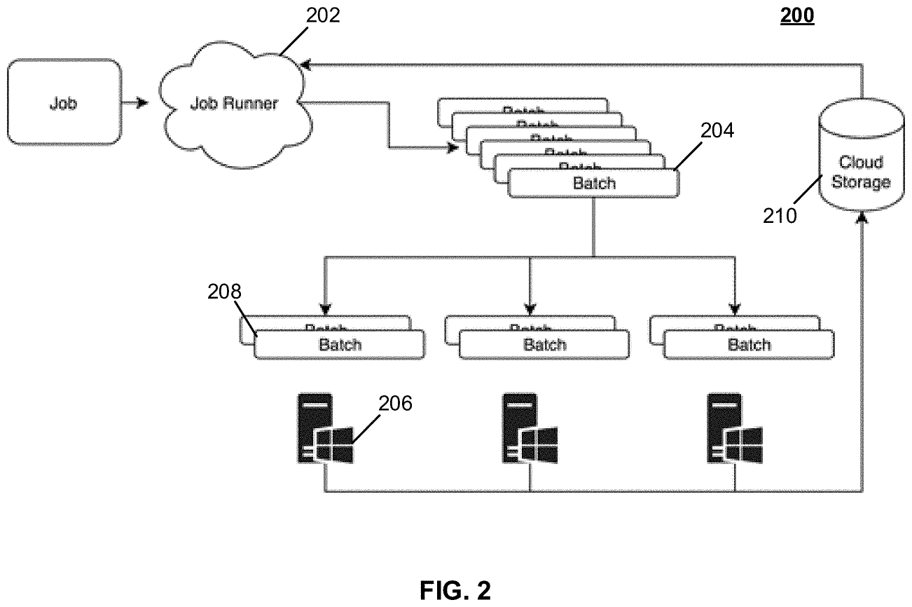

Turning to FIG. 2, an example 200 of a schematic diagram for generating and managing virtual machine instances to execute a simulation is shown in accordance with some embodiments of the disclosed subject matter. As illustrated, in some embodiments, schematic 200 can include a job runner 202, a group of batches 204, one or more virtual machine instances, such as virtual machine instance 206, one or more divided batches, such as divided batch 208, and/or cloud storage 210.

In some embodiments, job runner 202 can be any suitable program executing on a user device 306 that is executing a simulation. For example, in some embodiments, job runner 202 can be a program for splitting a simulation into different batches or iterations and placing each batch or iteration in a queue for retrieval by virtual machine instances. Additionally or alternatively, in some embodiments, job runner 202 can be a program for splitting a simulation into different batches or iterations and transmitting information associated with each batch or iteration to a different virtual machine instance for execution.

In some embodiments, group of batches 204 can correspond to any suitable group of blocks or iterations of a simulation. For example, each batch can correspond to a call to a particular function, a loop, and/or any other suitable block or iteration of code corresponding to the simulation. In some embodiments, group of batches 204 can include any suitable number of blocks or iterations (e.g., ten, twenty, one hundred, and/or any other suitable number).

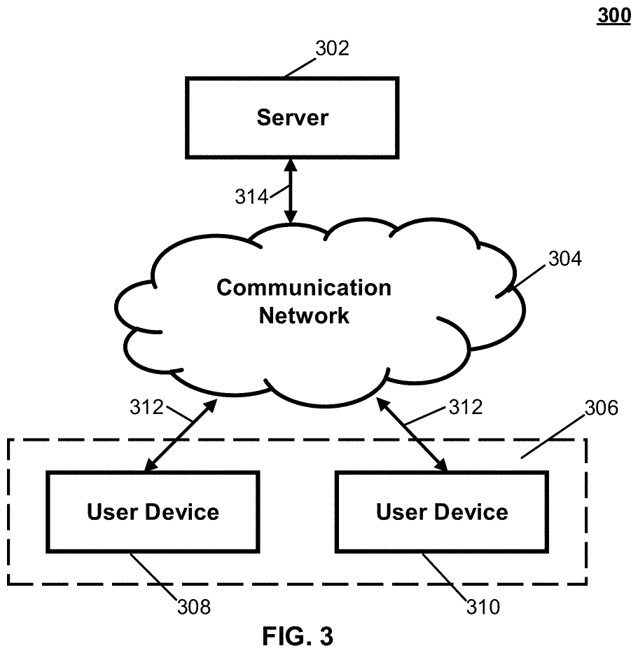

In some embodiments, virtual machine instance 206 can be any suitable virtual machine instance that has been generated and/or initialized based on instructions from job runner 202. In some embodiments, FIG. 2 can include any suitable number (e.g., one, two, ten, twenty, and/or any other suitable number) of virtual machine instances. In some embodiments, virtual machine instance 206 can be a virtual machine instance that has been generated and is executing on any suitable device, such as server 302, as shown in and described below in connection with FIG. 3. In some embodiments, virtual machine instance 206 can retrieve a block or an iteration from a queue, for example, a queue maintained and/or modified by job runner 202, as described above. For example, in some embodiments, virtual machine instance 206 can retrieve a block or an iteration from the queue, and can then obtain any files, additional software (e.g., plugins, and/or any other suitable software), and/or any other suitable content to execute the block or the iteration.

In some embodiments, divided batch 208 can correspond to a block of a simulation and/or an iteration of a simulation that is to be executed by virtual machine instance 206. For example, in some embodiments, divided batch 208 can correspond to a particular iteration of the simulation, a particular loop to be executed as part of the simulation, a particular function call to be executed as part of the simulation, and/or any other suitable block of the simulation.

In some embodiments, cloud storage 210 can be any suitable memory or other storage for storing information from group of virtual machine instances 206. For example, in some embodiments, cloud storage 210 can store intermediate results and/or final results from blocks executed on one or more virtual machine instances. As illustrated in FIG. 2, in some embodiments, cloud storage 210 can transmit information back to job runner 202. In some embodiments, cloud storage 210 can be associated with a server hosting virtual machine instances and can transmit information back to a user device associated with job runner 202.

Turning to FIG. 3, an example 300 of hardware for initiating and monitoring instances of workflows that can be used in accordance with some embodiments of the disclosed subject matter is shown. As illustrated, hardware 300 can include a server 302, a communication network 304, and/or one or more user devices 306, such as user devices 308 and 310.

Server 302 can be any suitable server(s) for storing information, data, programs, virtual machine instances, and/or any other suitable content. For example, in some embodiments, server 302 can receive any suitable instructions to execute steps, processes, or simulations included in a workflow and can execute the indicated steps, processes, or simulations in response to receiving the instruction. As another example, in some embodiments, server 302 can cause any suitable instructions to be executed on a virtual machine instance hosted by server 302. In some embodiments, server 302 can be associated with any suitable entity, such as an entity associated with a particular Infrastructure as a Service (IaaS) entity, and/or any other suitable entity.

Communication network 304 can be any suitable combination of one or more wired and/or wireless networks in some embodiments. For example, communication network 304 can include any one or more of the Internet, an intranet, a wide-area network (WAN), a local-area network (LAN), a wireless network, a digital subscriber line (DSL) network, a frame relay network, an asynchronous transfer mode (ATM) network, a virtual private network (VPN), and/or any other suitable communication network. User devices 306 can be connected by one or more communications links (e.g., communications links 312) to communication network 304 that can be linked via one or more communications links (e.g., communications links 314) to server 302. The communications links can be any communications links suitable for communicating data among user devices 306 and server 302 such as network links, dial-up links, wireless links, hard-wired links, any other suitable communications links, or any suitable combination of such links.

User devices 306 can include any one or more user devices suitable for initiating a workflow, transmitting instructions to server 302 to initiate a workflow, transmitting information indicating parameters for a particular process or simulation, presenting results of a workflow (e.g., results of a simulation, results of a sequence of processes or simulations, and/or any other suitable results), and/or performing any other suitable functions. In some embodiments, user devices 306 can include any suitable type(s) of user devices. For example, in some embodiments, user devices 306 can include a mobile phone, a tablet computer, a laptop computer, a desktop computer, and/or any other suitable type of user device.

Although server 302 is illustrated as one device, the functions performed by server 302 can be performed using any suitable number of devices in some embodiments. For example, in some embodiments, multiple devices can be used to implement the functions performed by server 302.

Although two user devices 308 and 310 are shown in FIG. 3 to avoid over-complicating the figure, any suitable number of user devices, and/or any suitable types of user devices, can be used in some embodiments.

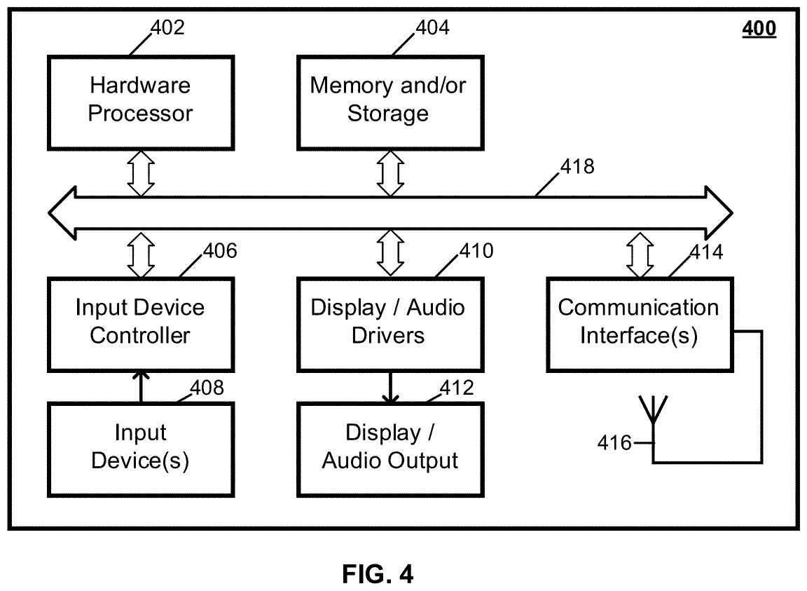

Server 302 and user devices 306 can be implemented using any suitable hardware in some embodiments. For example, in some embodiments, devices 302 and 306 can be implemented using any suitable general-purpose computer or special-purpose computer. For example, a mobile phone may be implemented using a special-purpose computer. Any such general-purpose computer or special-purpose computer can include any suitable hardware. For example, as illustrated in example hardware 400 of FIG. 4, such hardware can include hardware processor 402, memory and/or storage 404, an input device controller 406, an input device 408, display/audio drivers 410, display and audio output circuitry 412, communication interface(s) 414, an antenna 416, and a bus 418.

Hardware processor 402 can include any suitable hardware processor, such as a microprocessor, a micro-controller, digital signal processor(s), dedicated logic, and/or any other suitable circuitry for controlling the functioning of a general-purpose computer or a special-purpose computer in some embodiments. In some embodiments, hardware processor 402 can be controlled by a server program stored in memory and/or storage of a server, such as server 302. In some embodiments, hardware processor 402 can be controlled by a computer program stored in memory and/or storage of a user device, such as user device 306. For example, in some embodiments, hardware processor 402 of user device 306 can cause user device 306 to cause a workflow to be initiated, receive results from execution of the workflow, present results from received during execution of the workflow, and/or perform any other suitable function(s).

Memory and/or storage 404 can be any suitable memory and/or storage for storing programs, data, and/or any other suitable information in some embodiments. For example, memory and/or storage 404 can include random access memory, read-only memory, flash memory, hard disk storage, optical media, and/or any other suitable memory.

Input device controller 406 can be any suitable circuitry for controlling and receiving input from one or more input devices 408 in some embodiments. For example, input device controller 406 can be circuitry for receiving input from a touchscreen, from a keyboard, from one or more buttons, from a voice recognition circuit, from a microphone, from a camera, from an optical sensor, from an accelerometer, from a temperature sensor, from a near field sensor, from a pressure sensor, from an encoder, and/or any other type of input device.

Display/audio drivers 410 can be any suitable circuitry for controlling and driving output to one or more display/audio output devices 412 in some embodiments. For example, display/audio drivers 410 can be circuitry for driving a touchscreen, a flat-panel display, a cathode ray tube display, a projector, a speaker or speakers, and/or any other suitable display and/or presentation devices.

Communication interface(s) 414 can be any suitable circuitry for interfacing with one or more communication networks (e.g., computer network 304). For example, interface(s) 414 can include network interface card circuitry, wireless communication circuitry, and/or any other suitable type of communication network circuitry.

Antenna 416 can be any suitable one or more antennas for wirelessly communicating with a communication network (e.g., communication network 304) in some embodiments. In some embodiments, antenna 316 can be omitted.

Bus 418 can be any suitable mechanism for communicating between two or more components 402, 404, 406, 410, and 414 in some embodiments.

Any other suitable components can be included in hardware 300 in accordance with some embodiments.

In some embodiments, at least some of the above described blocks of the process of FIG. 1 can be executed or performed in any order or sequence not limited to the order and sequence shown in and described in connection with the figures. Also, some of the above blocks of FIG. 1 can be executed or performed substantially simultaneously where appropriate or in parallel to reduce latency and processing times. Additionally or alternatively, some of the above described blocks of the process of FIG. 1 can be omitted.

In some embodiments, any suitable computer readable media can be used for storing instructions for performing the functions and/or processes herein. For example, in some embodiments, computer readable media can be transitory or non-transitory. For example, non-transitory computer readable media can include media such as non-transitory forms of magnetic media (such as hard disks, floppy disks, and/or any other suitable magnetic media), non-transitory forms of optical media (such as compact discs, digital video discs, Blu-ray discs, and/or any other suitable optical media), non-transitory forms of semiconductor media (such as flash memory, electrically programmable read-only memory (EPROM), electrically erasable programmable read-only memory (EEPROM), and/or any other suitable semiconductor media), any suitable media that is not fleeting or devoid of any semblance of permanence during transmission, and/or any suitable tangible media. As another example, transitory computer readable media can include signals on networks, in wires, conductors, optical fibers, circuits, any suitable media that is fleeting and devoid of any semblance of permanence during transmission, and/or any suitable intangible media.

Accordingly, methods, systems, and media for initiating and monitoring instances of workflows are provided.

Although the invention has been described and illustrated in the foregoing illustrative embodiments, it is understood that the present disclosure has been made only by way of example, and that numerous changes in the details of implementation of the invention can be made without departing from the spirit and scope of the invention. Features of the disclosed embodiments can be combined and rearranged in various ways.

What is claimed is:

1. A method for monitoring workflows for generating multiple design iterations, the method comprising:
retrieving, using a hardware processor, a workflow description that includes a plurality of steps and that corresponds to a group of simulations in a generative design system for generating a plurality of design iterations;
generating, using the hardware processor, a graph that represents a workflow and that indicates interconnections between the plurality of steps;
determining, using the hardware processor, information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps;
determining, using the hardware processor, an execution strategy for performing the plurality of steps included in the workflow based on the determined information for the generative design system;
causing, using the hardware processor, the generative design system to execute the plurality of steps in the workflow using the execution strategy; and
updating, using the hardware processor, a user interface with one or more design iterations of the plurality of design iterations upon generation by the generative design system.

2. The method of claim 1, wherein generating the graph further comprises determining, based on the workflow description, that a first step in the workflow is to be performed prior to performing a second step in the workflow.

3. The method of claim 2, further comprising determining that an output value generated from the first step in the workflow is to be applied during execution of the second step in the workflow, wherein the information for the generative design system includes identifying a compatibility layer to communicate between the output value generated from the first step and the second step in the workflow.

4. The method of claim 1, wherein generating the graph further comprises determining, based on the workflow description, that a first step in the workflow and a second step in the workflow are to be executed concurrently.

5. The method of claim 1, wherein determining that the first subset of steps are to be batched together as the first batch based on a determination that there are no dependencies between steps in the first subset of steps.

6. The method of claim 1, wherein the information for the generative design system includes identifying resources required for each step in the workflow and wherein determining that the first subset of steps are to be batched together as the first batch based on a determination that there are no resource conflicts between steps in the first subset of steps.

7. The method of claim 1, further comprising determining that one or more virtual machine instances are to be generated to execute a portion of the workflow.

8. A system for monitoring workflows for generating multiple design iterations, the system comprising:
a memory; and
a hardware processor that, when configured to execute computer executable instructions stored in the memory, is configured to:
retrieve a workflow description that includes a plurality of steps and that corresponds to a group of simulations in a generative design system for generating a plurality of design iterations;
generate a graph that represents a workflow and that indicates interconnections between the plurality of steps;
determine information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps;
determine an execution strategy for performing the plurality of steps included in the workflow based on the determined information for the generative design system;
cause the generative design system to execute the plurality of steps in the workflow using the execution strategy; and
update a user interface with one or more design iterations of the plurality of design iterations upon generation by the generative design system.

9. The system of claim 8, wherein generating the graph further comprises determining, based on the workflow description, that a first step in the workflow is to be performed prior to performing a second step in the workflow.

10. The system of claim 9, wherein the hardware processor is further configured to determine that an output value generated from the first step in the workflow is to be applied during execution of the second step in the workflow, wherein the information for the generative design system includes identifying a compatibility layer to communicate between the output value generated from the first step and the second step in the workflow.

11. The system of claim 8, wherein generating the graph further comprises determining, based on the workflow description, that a first step in the workflow and a second step in the workflow are to be executed concurrently.

12. The system of claim 8, wherein determining that the first subset of steps are to be batched together as the first batch based on a determination that there are no dependencies between steps in the first subset of steps.

13. The system of claim 8, wherein the information for the generative design system includes identifying resources required for each step in the workflow and wherein determining that the first subset of steps are to be batched together as the first batch based on a determination that there are no resource conflicts between steps in the first subset of steps.

14. The system of claim 8, wherein the hardware processor is further configured to determine that one or more virtual machine instances are to be generated to execute a portion of the workflow.

15. A non-transitory computer-readable medium containing computer executable instructions that, when executed by a hardware processor, cause the hardware processor to perform a method for monitoring workflows for generating multiple design iterations, the method comprising:
retrieving, using the hardware processor, a workflow description that includes a plurality of steps and that corresponds to a group of simulations in a generative design system for generating a plurality of design iterations;
generating, using the hardware processor, a graph that represents a workflow and that indicates interconnections between the plurality of steps;
determining, using the hardware processor, information for the generative design system to performs the plurality of steps included in the workflow based on the graph, wherein the information for the generative design system includes determining that a first subset of steps are to be batched together as a first batch and determining that a second subset of steps are to be batched together as a second batch, and wherein the first batch and the second batch are executed as a group of steps;
determining, using the hardware processor, an execution strategy for performing the plurality of steps included in the workflow based on the determined information for the generative design system;
causing, using the hardware processor, the generative design system to execute the plurality of steps in the workflow using the execution strategy; and
updating, using the hardware processor, a user interface with one or more design iterations of the plurality of design iterations upon generation by the generative design system.

16. The non-transitory computer-readable medium of claim 15, wherein generating the graph further comprises determining, based on the workflow description, that a first step in the workflow is to be performed prior to performing a second step in the workflow.

17. The non-transitory computer-readable medium of claim 16, wherein the method further comprises determining that an output value generated from the first step in the workflow is to be applied during execution of the second step in the workflow, wherein the information for the generative design system includes identifying a compatibility layer to communicate between the output value generated from the first step and the second step in the workflow.

18. The non-transitory computer-readable medium of claim 15, wherein generating the graph further comprises determining, based on the workflow description, that a first step in the workflow and a second step in the workflow are to be executed concurrently.

19. The non-transitory computer-readable medium of claim 15, wherein determining that the first subset of steps are to be batched together as the first batch based on a determination that there are no dependencies between steps in the first subset of steps.

20. The non-transitory computer-readable medium of claim 15, wherein the information for the generative design system includes identifying resources required for each step in the workflow and wherein determining that the first subset of steps are to be batched together as the first batch based on a determination that there are no resource conflicts between steps in the first subset of steps.

21. The non-transitory computer-readable medium of claim 15, wherein the method further comprises determining that one or more virtual machine instances are to be generated to execute a portion of the workflow.
